(19) United States
(12) Patent Application Publication
(10) Pub. No.: US 2015/0214183 A1
(43) Pub. Date: Jul. 30, 2015

(54) SEMICONDUCTOR DEVICE AND METHOD OF FABRICATING THE SAME

(71) Applicant: Kabushiki Kaisha Toshiba, Tokyo (JP)

(72) Inventor: Yoshiaki Inoue, Chiba-shi (JP)

(21) Appl. No.: 14/319,315

(22) Filed: Jun. 30, 2014

(30) Foreign Application Priority Data
Jan. 29, 2014 (JP) 2014-014671

(51) Int. Cl. H01L 23/00; B23K 1/00

(52) U.S. Cl. CPC H01L 24/83; H01L 24/32; B23K 1/0016; H01L 2224/83203; H01L 2924/014

(57) ABSTRACT

According to one embodiment, in a fabrication method of a semiconductor device, heating is conducted at a temperature higher than a first liquid phase temperature of the adhesive member. The semiconductor element and the one end of the first connector are bonded to each other, and the second electrode terminal and the other end of the first connector are bonded to each other. Cooling to a temperature lower than the first solid phase temperature of the adhesive member is conducted. The first connector, the adhesive member, the semiconductor element, the first electrode terminal, and the second electrode terminal are pressurized with heating at a temperature between the first solid phase temperature and a first liquid phase temperature of the adhesive member.

### CROSS REFERENCE TO RELATED APPLICATION

This application is based upon and claims the benefit of priority from the prior Japanese Patent Application No. 2014-014671, filed on Jan. 29, 2014, the entire contents of which are incorporated herein by reference.

### FIELD

Embodiments described here relate to a semiconductor device and a method of fabricating the semiconductor device.

### BACKGROUND

In semiconductor devices installed an IGBT (Insulated Gate Bipolar Transistor), a power MOSFET (Metal Oxide Semiconductor Field Effect Transistor) and a power IC, or the like, a connector is frequently used to connect between an electrode of a semiconductor element and an electrode terminal.

### BRIEF DESCRIPTION OF THE DRAWINGS

FIG. 1 is a plane view showing a semiconductor device according to a first embodiment,

FIG. 2 is a sectional view of the semiconductor device shown in FIG. 1 taken along a line A-A,

FIGS. 3A and 3B are diagrams showing a processing sequence in a fabrication method of the semiconductor device according to the first embodiment, FIG. 3A is a diagram showing a temperature sequence, and FIG. 3B is a diagram showing a pressure sequence,

FIG. 4 is a sectional view showing a semiconductor device under fabrication in the fabrication method of the semiconductor device according to the first embodiment,

FIG. 5 is a sectional view showing a semiconductor device under fabrication in the fabrication method of the semiconductor device according to the first embodiment,

FIG. 6 is a sectional view showing a semiconductor device under fabrication in the fabrication method of the semiconductor device according to the first embodiment,

FIGS. 7A and 7B are diagrams showing dispersion of height of a semiconductor element according to the first embodiment, FIG. 7A is a diagram showing the embodiment, and FIG. 7B is a diagram showing a conventional example,

FIG. 8 is a comparison diagram of dispersion of height of the semiconductor element according to the first embodiment,

FIG. 9 is a sectional view showing a semiconductor device according to a second embodiment,

FIG. 10 is a sectional view showing a semiconductor device under fabrication in a fabrication method of the semiconductor device according to the second embodiment, and

FIGS. 11A and 11B are diagrams showing temperature and pressure in a fabrication method of a semiconductor device according to a first modification, FIG. 11A is a diagram showing a temperature sequence, and FIG. 11B is a diagram showing a pressure sequence.

### DETAILED DESCRIPTION

According to one embodiment, in a fabrication method of a semiconductor device, one end of a first connector is provided on a first electrode of a semiconductor element on a first electrode terminal via a first portion of an adhesive member, and the other end of the first connector is placed on a second electrode terminal via a second portion of the adhesive member. Heating is conducted at a temperature higher than a first liquid phase temperature of the adhesive member. The semiconductor element and the one end of the first connector are bonded to each other, and the second electrode terminal and the other end of the first connector are bonded to each other. Cooling to a temperature lower than the first solid phase temperature of the adhesive member is conducted. The first connector, the adhesive member, the semiconductor element, the first electrode terminal, and the second electrode terminal are pressurized with heating at a temperature between the first solid phase temperature and a first liquid phase temperature of the adhesive member.

Hereafter, a plurality of embodiments will be described with reference to the drawings. In the drawings, the same character denotes the same or like portions.

In a semiconductor device using a connector, there is the following problem. When an area of an electrode is increased so as to pass a large current through a semiconductor element, an area of the connector increases. In a case where an electrode and an electrode terminal are connector-coupled, dispersion of height of a semiconductor element increases, resulting in the problem. When the dispersion of height of the semiconductor element increases, lowering of yield and reliability of the semiconductor device occurs. In the semiconductor device using the connector, it is necessary to suppress the dispersion of height of the semiconductor element. Here, the semiconductor element is a power discrete semiconductor device, a power IC, and the like.

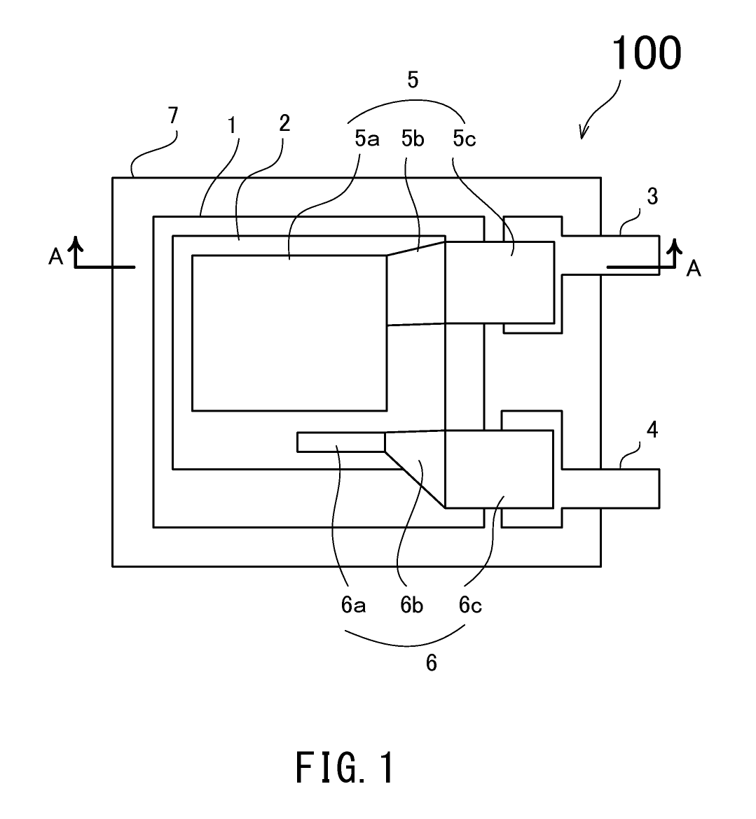

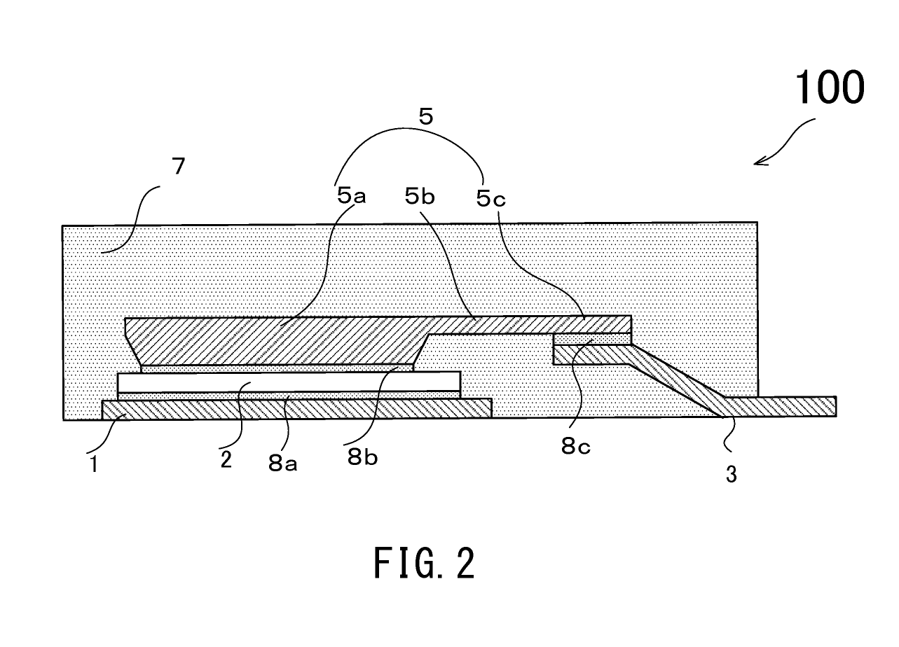

A semiconductor device according to a first embodiment will be described with reference to the drawings. FIG. 1 is a plane view showing a semiconductor device. FIG. 2 is a sectional view of the semiconductor device taken along a line A-A in FIG. 1. In the embodiment, a semiconductor element and one end of a connector, and an electrode terminal and the other end of the connector are bonded via solder at a temperature higher than a solid phase temperature of solder. After cooling, heating and pressurization processing is applied to the semiconductor element, the connector, and the electrode terminal at a temperature between the solid phase temperature and a liquid phase temperature of solder.

As shown in FIG. 1, a semiconductor device 100 includes an electrode terminal 1, a semiconductor element 2, an electrode terminal 3, an electrode terminal 4, a connector 5, a connector 6, and a sealing member 7. The semiconductor device 100 is a connector-bonded type semiconductor device in which the semiconductor element 2 is sealed by the sealing member 7 and the electrode terminals and the electrodes of the semiconductor element 2 are bonded by the connector. The semiconductor device 100 is applied to various fields such as an electric railroad application field, an electric automobile, an inverter field, and an induction heating field.

The semiconductor element 2 is an IGBT (insulated gate bipolar transistor). The electrode terminal 1 is a collector electrode terminal. The electrode terminal 3 is an emitter electrode terminal. The electrode terminal 4 is a gate electrode terminal.

The semiconductor element 2 is provided on the electrode terminal 1. The connector 5 includes component parts 5a to 5c. The component part 5a of the connector 5 is provided on an emitter electrode (first electrode), which is not shown, of the semiconductor element 2. The component part 5c of the connector 5 is provided on the electrode terminal 3. The component part 5b of the connector 5 couples the component part 5a of the connector 5 and the component part 5c of the connector 5. The connector 6 includes component parts 6a to 6c. The component part 6a of the connector 6 is provided on a gate electrode (second electrode), which is not shown, of the semiconductor element 2. The component part 6c of the connector 6 is provided on the electrode terminal 4. The component part 6b of the connector 6 couples the component part 6a of the connector 6 and the component part 6c of the connector 6.

The electrode terminal 1, the semiconductor element 2, the electrode terminal 3, the electrode terminal 4, the connector 5, and the connector 6 are sealed by the sealing member 7. In the figure, right end parts of the electrode terminal 3 and the electrode terminal 4 are exposed.

The connector 5, the connector 6, the electrode terminal 1, the electrode terminal 3, and the electrode terminal 4 include Cu (copper), for example. The sealing member 7 includes epoxy resin, for example. Here, the connectors 5 and 6 include Cu (copper). Instead, however, a Cu (copper) alloy, Mo (molybdenum), or AlSiC may be used. Although the sealing member 7 includes epoxy resin, silicone resin may be used instead.

The semiconductor element 2 which is an IGBT is designed to have an area of the emitter electrode larger than that of the gate electrode. In order to be connector-bonded to the emitter electrode having a relatively larger area, the component part 5a of the connector 5 is set to be larger in area then the component part 6a of the connector 6. As a result, it is possible to pass a relatively large current through the emitter electrode.

As shown in FIG. 2, the semiconductor element 2 is provided on a principal surface (surface side) of the electrode terminal 1 via an adhesive member 8a. The adhesive member 8a connects the electrode terminal 1 and a collector electrode (third electrode) which is provided on a back side of the semiconductor element 2 and which is not shown. A back side of the electrode terminal 1 opposite to the principal surface is exposed. The component part 5a of the connector 5 is provided on a principal surface (surface side) of the semiconductor element 2 via an adhesive member 8b. The adhesive member 8b connects the emitter electrode (first electrode) of the semiconductor element 2 and the component part 5a (one end) of the connector 5. An adhesive member 8c connects the electrode terminal 3 and the component part 5c (the other end) of the connector 5.

As for the electrode terminal 3, a portion of the electrode terminal 3 connected to the component part 5c of the connector 5 via the adhesive member 8c is provided in a higher position as compared with the electrode terminal 1. However, a portion (outer lead portion) of the electrode terminal 3 that is not sealed by the sealing member 7 is provided in a position of the same height as that of the electrode terminal 1.

In the same way, a portion of the electrode terminal 4 connected to the component part 6c of the connector 6 via an adhesive member is provided in a higher position as compared with the electrode terminal 1, although not shown. However, a portion (outer lead portion) of the electrode terminal 4 that is not sealed by the sealing member 7 is provided in a position of the same height as that of the electrode terminal 1.

The adhesive members 8a to 8c include solder of Sn (tin)—Ge (germanium). By the way, instead of the solder of Sn (tin)—Ge (germanium), solder of any of Sn—Zn (zinc), Sb—Ag (silver)-Cu—Sn, Pb (lead)-In (indium)-Ag, Pb—Sn, or the like, may be used.

Solder of Sn—Ge, Sn—Zn, Sb—Ag—Cu—Sn, Pb—In—Ag, and Pb—Sn has characteristics that the liquid phase temperature is 260° C. or higher than 260° C. and the solid-liquid phase temperature difference is 10° C. or higher than 10° C. The solid-liquid phase temperature difference is a temperature difference between solid phase and liquid phase. It is possible to remarkably reduce dispersion of height of the semiconductor element 2 which is comparatively large in the area of the emitter electrode by using solder having such characteristics (details will be described later).

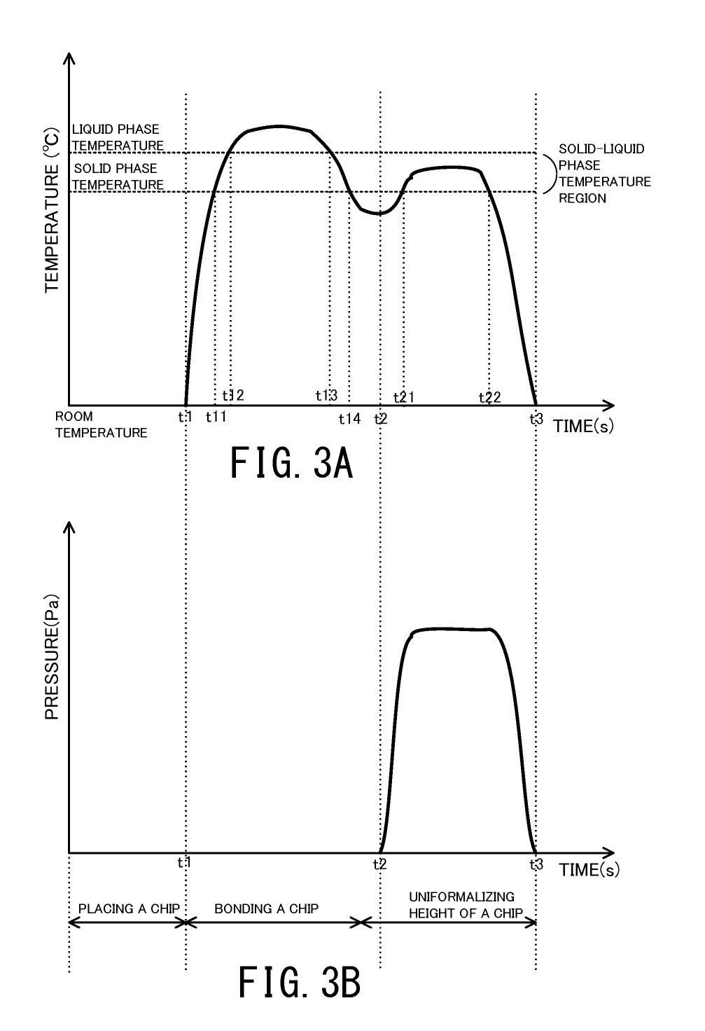

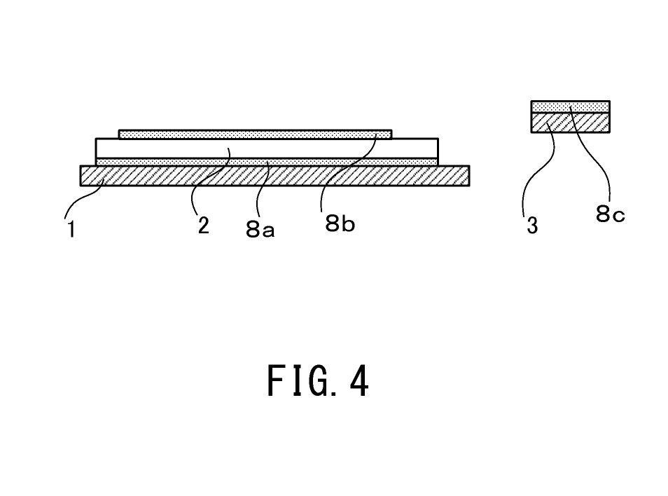

A fabrication method of the semiconductor device will be described with reference to FIGS. 3A to 6. FIG. 3A is a diagram showing a temperature processing sequence in the fabrication method of the semiconductor device. FIG. 3B is a diagram showing a pressure processing sequence in the fabrication method of the semiconductor device. FIGS. 4 to 6 are sectional views showing the semiconductor device under fabrication in the fabrication method of the semiconductor device.

First, as shown in FIG. 4, the semiconductor element 2 is provided on the electrode terminal 1 via the adhesive member 8a, and the adhesive member 8b is provided on the semiconductor element 2. The adhesive member 8c is provided on the electrode terminal 3. At this time, the chip placing process is performed at the room temperature without pressurization as shown in FIGS. 3A and 3B.

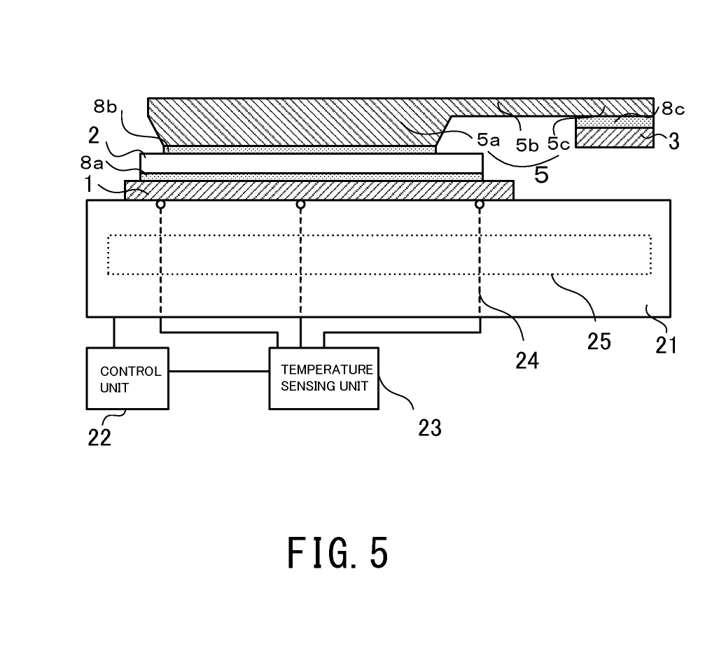

Then, as shown in FIG. 5, a laminate of the electrode terminal 1, the adhesive member 8a, the semiconductor element 2, and the adhesive member 8b are placed on a plate 21 in which a plurality of thermocouples 24 and a heater 25 are provided. The component part 5a (one end) of the connector 5 is provided on the adhesive member 8b. The component part 5c (the other end) of the connector 5 is provided on the adhesive member 8c.

As shown in FIGS. 3A and 3B, the plate 21 is heated from the room temperature. Temperature of the adhesive members 8a to 8c is raised to a first solid phase temperature or higher than first liquid phase temperature, for example. Then, the temperature of the adhesive members 8a to 8c is lowered to the first solid phase temperature or below. As a result, the electrode terminal 1 and the semiconductor element 2 are bonded by the adhesive member 8a, the semiconductor element 2 and the component part 5a of the connector 5 are bonded by the adhesive member 8b, and the electrode terminal 3 and the component part 5c of the connector 5 are bonded by the adhesive member 8c. The chip bonding process is performed without pressurization.

Specifically, temperature of the electrode terminal 1 is monitored by the plurality of thermocouples 24 having tip portions provided on a surface of the plate 21, and results of temperature monitoring are input to a temperature sensing unit 23. A control unit 22 controls to raise temperature of the heater 25 to the first solid phase temperature or higher than the first liquid phase temperature, for example, based on the results of temperature monitoring are input to a temperature sensing unit 23. As shown in FIG. 3A, the chip bonding process is performed between time t1 and time t2. For a time period between time t11 and time t14, the adhesive members 8a to 8c are set to the first solid phase temperature or higher than the first solid phase temperature. For a time period between time t12 and time t13, the adhesive members 8a to 8c are set to the first liquid phase temperature or higher than the first liquid phase temperature.

Here, the adhesive members 8a to 8c are set to the first liquid phase temperature or higher than the first liquid phase temperature. However, the temperature is not limited to the first liquid phase temperature or higher than the first liquid phase temperature. The temperature may be set between the first solid phase temperatures and the first liquid phase temperature, for example.

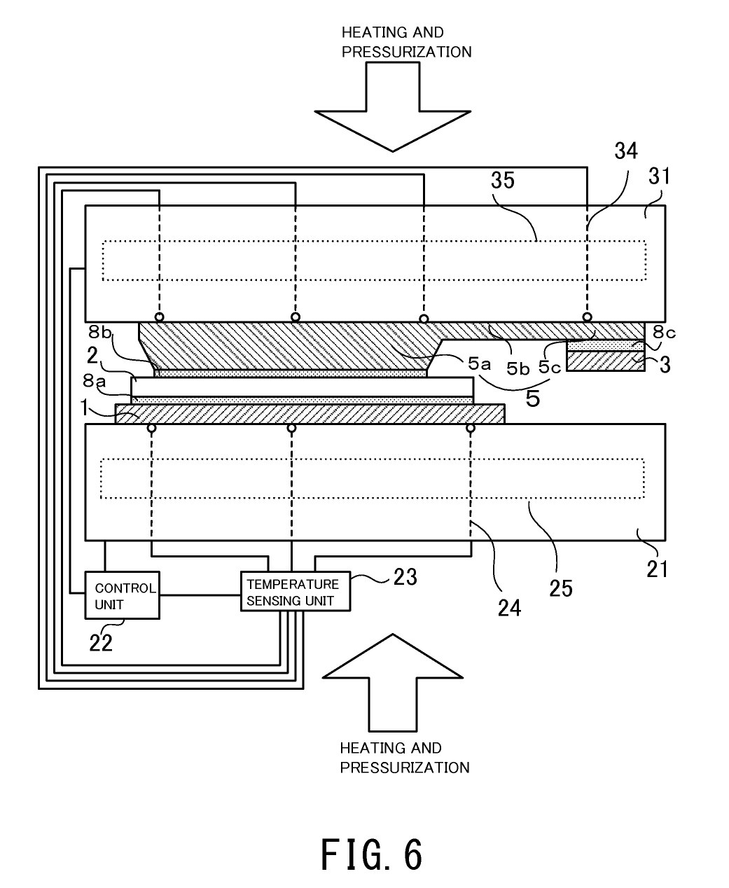

Subsequently, as shown in FIG. 6, a plate 31 in which a plurality of thermocouples 34 and a heater 35 are provided is placed on the connector 5.

As shown in FIGS. 3A and 3B, the temperature of the adhesive members 8a to 8c is raised from the first solid phase temperature or below to a temperature between the first solid phase temperature and the first liquid phase temperature by using the plate 21 and the plate 31. At the same time, the electrode terminal 1, the semiconductor element 2, the electrode terminal 3, the connector 5, and the adhesive members 8a to 8c are pressurized by using the plate 21 and the plate 31.

Specifically, the temperature of the electrode terminal 1 is monitored by the plurality of thermocouples 24 having tip portions provided on the surface of the plate 21, the temperature of the connector 5 is monitored by the plurality of thermocouples 34 having tip portions provided on the surface of the plate 31, and results of temperature monitoring are input to the temperature sensing unit 23. The control unit 22 controls to raise temperatures of the heater 25 and the heater 35 to a temperature between the first solid phase temperature and the first liquid phase temperature. At the same time, the electrode terminal 1, the semiconductor element 2, the electrode terminal 3, the connector 5, and the adhesive members 8a to 8c are pressurized from an upper side by the plate 31, and the electrode terminal 1, the semiconductor element 2, the electrode terminal 3, the connector 5, and the adhesive members 8a to 8c are pressurized from a lower side by the plate 21. In the heating and pressurization process, it is possible to remarkably reduce the dispersion of height of the semiconductor element 2 connected to the electrode terminal 1 by the adhesive member 8a and connected to the connector 5 by the adhesive member 8b.

As shown in FIGS. 3A and 3B, the element height uniformalizing process is performed between time t2 and time t3. For a time period between time t21 and the t22, the temperature is set to a temperature between the first solid phase temperature and the first liquid phase temperature. Pressurization is started at the time t2 and the pressurization is finished at the time t3.

As for the adhesive members 8a to 8c, solder having characteristics that the liquid phase temperature is equal to or higher than 260° C. and a temperature difference between solid phase and the solid-liquid phase temperature difference is equal to or higher than 10° C. is used. Therefore, the solid-liquid phase temperature difference is large. For the time period between the time t21 and the time t22, therefore, the temperature of the adhesive members 8a to 8c can be set between the first solid phase temperature and the first liquid phase temperature, and the temperature does not deviate from the temperature region. Furthermore, since high temperature solder having the liquid phase temperature of 260° C. or higher than 260° C. is used, it is possible to improve the yield and reliability of the semiconductor device 100.

After the element height uniformalizing process, the surface and side faces of the electrode terminal 1, the semiconductor element 2, the electrode terminal 3, the electrode terminal 4, the connector 5, the connector 6, and the adhesive members 8a to 8c are sealed by the sealing member 7. The electrode terminal 3 and the electrode terminal 4 are cut to a predetermined length, and the semiconductor device 100 is completed.

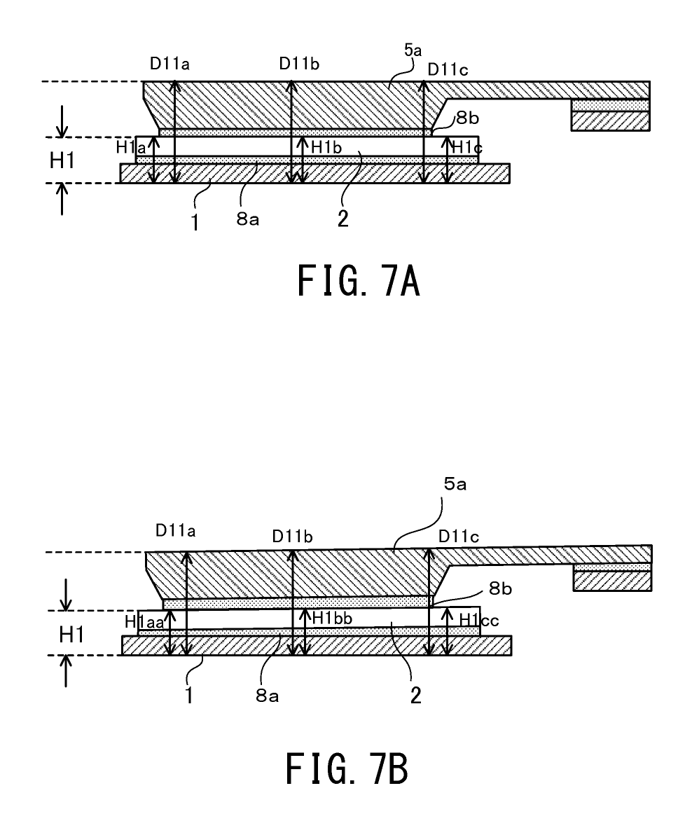

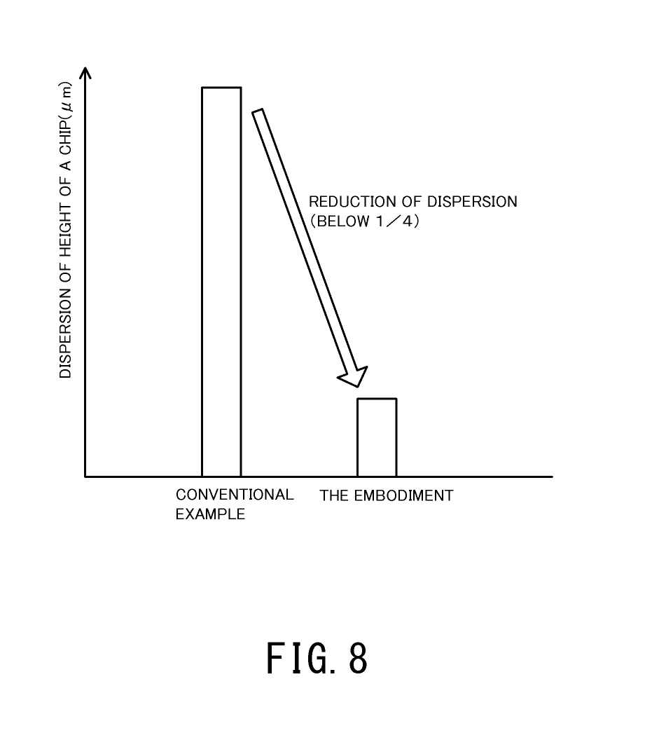

Dispersion of the height of the semiconductor element 2 bonded to the electrode terminal 1 by the adhesive member 8a and bonded to the connector 5 by the adhesive member 8b will now be described with reference to FIGS. 7A, 7B and 8.

As shown in FIG. 7A, in the embodiment, the chip placing process, the chip bonding process, and the element height uniformalizing process using heating and pressurization are performed. In the element height uniformalizing process using heating and pressurization, while a distance D11a from a bottom of the electrode terminal 1 at the left periphery portion to a top surface of the component part 5a, a distance D11b from a bottom of the electrode terminal 1 at the central portion to a top surface of the component part 5a, and a distance D11a from a bottom of the electrode terminal 1 at the right periphery portion to a top surface of the component part 5a are held the same distance, heating and pressurization are performed. Consequently, it is possible to remarkably reduce dispersion of the height of the semiconductor element 2 including an element height H1a at the left periphery portion of the semiconductor element 2, an element height H1b at the central portion, and an element height H1c at the right periphery portion shown in FIG. 7A.

As shown in FIG. 7B, in a conventional example in which the chip placing process and an bonding process using heating, a distance D11a from a bottom of the electrode terminal 1 at the left periphery portion to a top surface of the component part 5a, a distance D11b from a bottom of the electrode terminal 1 at the central portion to a top surface of the component part 5a, and a distance D11a from a bottom of the electrode terminal 1 at the right periphery portion to a top surface of the component part 5a are not held the same distance. Consequently, dispersion of height of the semiconductor element 2 including an element height H1aa at the left periphery portion of the semiconductor element 2, an element height H1bb at the central portion, and an element height H1cc at the right periphery portion becomes large.

Specifically, in the embodiment, the dispersion of height of the semiconductor element 2 can be reduced to one fourth as compared with that of the conventional example as shown in FIG. 8. Whereas the height dispersion (1σ) is in the range of 10 to 20 μm in the conventional example, the height dispersion (1σ) can be reduced to 4 μm or less, for example, in the embodiment.

By the way, for height measurement of the semiconductor element 2, a focal depth meter in a metallographic microscope, a laser discrimination displacement sensor, or a low magnification SEM (Scanning Electron Microscope), for example, is used.

As compared with a case where coupling using adhesive members is performed in only the heating process and pressurization process although not shown, in the embodiment the element height uniformalizing process using heating and pressurization is added and performed. As a result, it is possible to reduce the height dispersion of the semiconductor element 2.

In the fabrication method of the semiconductor device according to the embodiment, the chip placing process, the chip bonding process, and the element height uniformalizing process are performed as described above.

Consequently, it is possible to remarkably reduce the height dispersion of the semiconductor element 2 having a large area of an electrode, and improve yield and reliability of the semiconductor device 100 having the sealed semiconductor element 2.

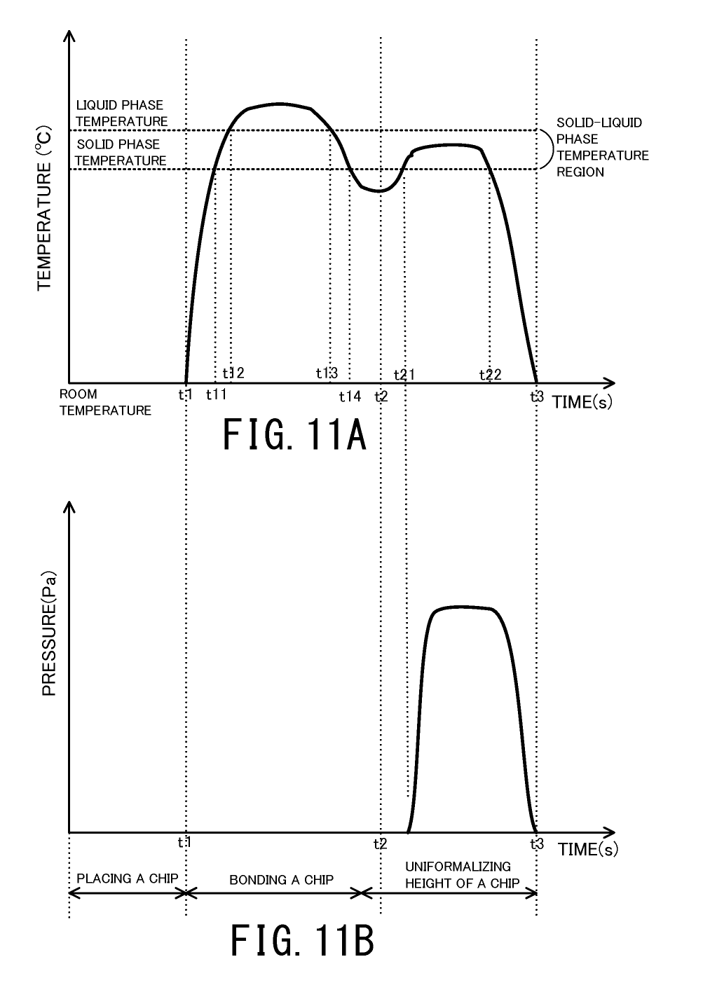

In the embodiment, heating and pressurization are started from the time t2. However, it is not restrictive. As in a first modification shown in FIGS. 11A and 11B, pressurization may be started from the time t21 when the first solid phase temperature is reached.

Furthermore, the IGBT is used as the semiconductor element 2. However, a power MOSFET or a power IC may be used instead. In a case of the power IC, the number of electrodes becomes greater as compared with that of a discrete semiconductor device. After the element height uniformalizing process, therefore, it is necessary to perform bonding wire connection besides the connector connection. Since bonding wire connection is performed after connection using the connector, it is desirable to use solder that is comparatively high in solid phase temperature as the adhesive member. It is desirable to use solder of Sb—Ag—Cu—Sn, Pb—In—Ag, or Pb—Sn having characteristics that the solid phase temperature is 260° C. or higher than 260° C. and the solid-liquid phase temperature difference is 10° C. or higher than 10° C., for example.

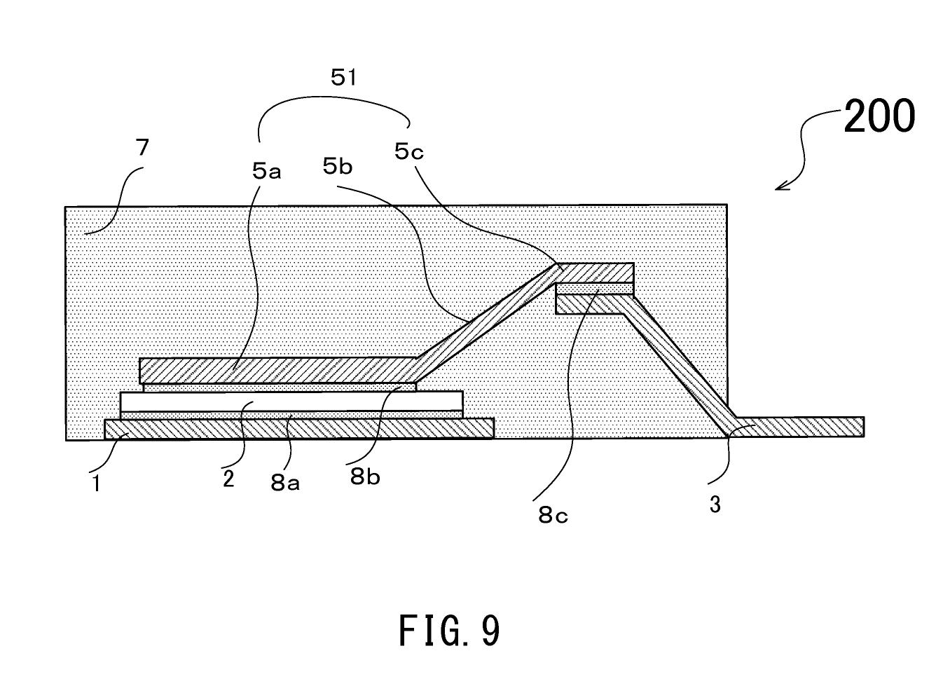

A semiconductor device according to a second embodiment will be described with reference to the drawings. FIG. 9 is a sectional view showing the semiconductor device. In the embodiment, the shape of the upper plate is changed to cope with a connector having a height at the one end remarkably different from a height at the other end and having a shape of uneven levels.

Hereafter, the same component portion as that in the first embodiment is denoted by the same character, and description of the portion will be omitted. Only different portions will be described.

As shown in FIG. 9, the electrode terminal 1, the semiconductor element 2, the electrode terminal 3, a connector 51, the adhesive members 8a to 8c, and the sealing member 7 are provided in the semiconductor device 200. The semiconductor device 200 is a connector-bonded type semiconductor device in which the semiconductor element 2 is sealed by the sealing member 7 and the electrode terminals and the electrodes of the semiconductor element 2 are bonded by the connector. The semiconductor device 200 is applied to various fields such as an electric railroad application field, an electric automobile, an inverter field, and an induction heating field.

A component part 5a (one end) of the connector 51 is provided on the semiconductor element 2 via the adhesive member 8b. A component part 5c (the other end) of the connector 51 is provided on the electrode terminal 3 via the adhesive member 8c. In the embodiment, the electrode terminal 3 is disposed to be higher than the electrode terminal in the first embodiment, and the connector 51 has a structure with uneven levels.

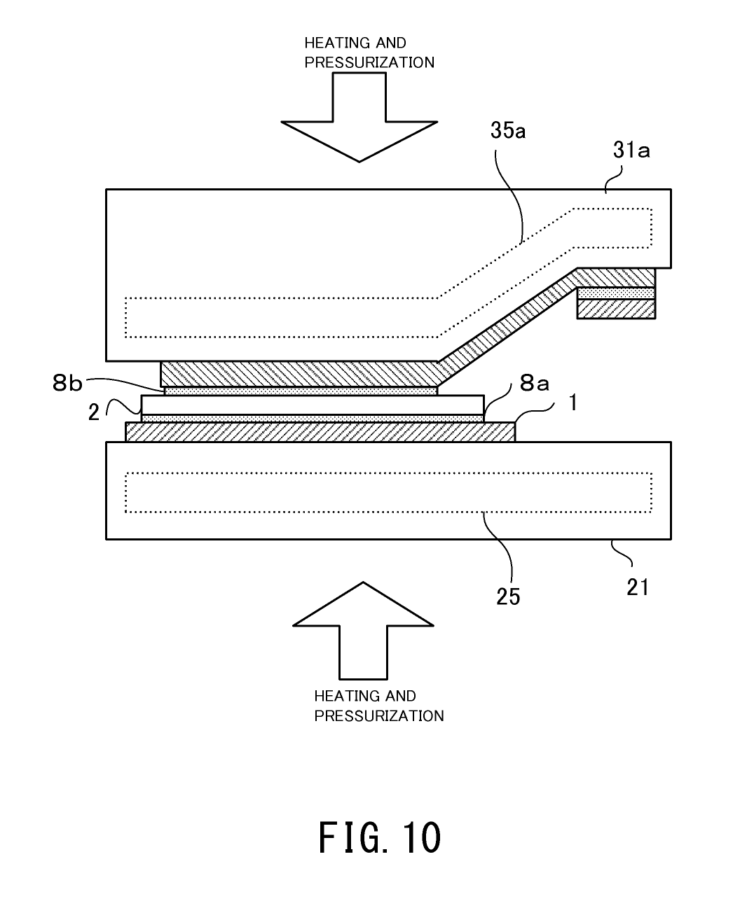

A fabrication method of the semiconductor device will be described with reference to FIG. 10. FIG. 10 is a sectional view showing the semiconductor device under fabrication in the fabrication method of the semiconductor device.

As shown in FIG. 10, a plate 31a takes a shape to come in contact with the component part 5a, the component part 5b, and the component part 5c of the connector 51. A heater 35a provided within the plate 31a has a structure to be disposed at equal distances from the component part 5a, the component part 5b, and the component part 5c of the connector 51 in order to uniformly transfer heat to the component part 5a, the component part 5b, and the component part 5c of the connector 51.

Consequently, heating and pressurization using the plate 21 and the plate 31a are performed uniformly. Even the connector 51 having uneven levels is used, planarization of the semiconductor element 2 is performed uniformly. Here, as for a plurality of thermocouples provided within the plate 21 and the plate 31a, illustration and description are omitted.

As described above, in the fabrication method of the semiconductor device according to the embodiment, heating and pressurization are performed by using the plate 31a taking a shape to come in contact with the component part 5a, the component part 5b, and the component part 5c of the connector 51 having uneven levels, and the plate 21.

Even in the case of the connector 51 having a large level difference, therefore, it is possible to remarkably reduce the height dispersion of the semiconductor element 2 and improve the yield and reliability of the semiconductor device 200 having the sealed semiconductor element 2.

Several embodiments according to the invention have been described, but these embodiments are presented as examples, which are not intended to limit the scope of the invention. These novel embodiments can be implemented in various other forms, and various omissions, substitutions, and changes can be made in a scope not departing from the spirit of the invention. These embodiments and the modifications are included in the scope or spirit of the invention, and also in the equivalent scope of claims of the invention.

What is claimed is:

1. A fabrication method of semiconductor device comprising:
providing one end of a first connector on a first electrode of a semiconductor element on a first electrode terminal, via a first portion of an adhesive member, and providing the other end of the first connector on a second electrode terminal via a second portion of the adhesive member;
heating at a temperature higher than a first liquid phase temperature of the adhesive member, and then bonding the semiconductor element and the one end of the first connector, bonding the second electrode terminal and the other end of the first connector, and then cooling to a temperature lower than a first solid phase temperature of the adhesive member; and
pressurizing the first connector, the adhesive member, the semiconductor element, the first electrode terminal, and the second electrode terminal with heating the first connector, the adhesive member, the semiconductor element, the first electrode terminal, and the second electrode terminal at a temperature between the first solid phase temperature and a first liquid phase temperature of the adhesive member.

2. The method according to claim 1, wherein
A third portion of the adhesive member is provided between the first electrode terminal and the semiconductor element, and is heated at a temperature higher than the first liquid phase temperature, and the first electrode terminal and the semiconductor element are bonded simultaneously.

3. The method according to claim 1, wherein
the adhesive member is solder having characteristics that a liquid phase temperature is equal to 260° C. or higher than 260° C. and a temperature difference between solid phase and liquid phase is equal to 10° C. or higher than 10° C.

4. The method according to claim 3, wherein
the adhesive member is solder selected any one of Sn—Ge, Sn—Zn, Sb—Ag—Cu—Sn, Pb—In—Ag, and Pb—Sn.

5. The method according to claim 1, wherein
after the pressurizing process, a second electrode of the semiconductor element and a third electrode terminal are connected by a bonding wire.

6. The method according to claim 1, wherein
the adhesive member is solder having characteristics that a solid phase temperature is equal to 260° C. or higher than 260° C. and a temperature difference between solid phase and liquid phase is equal to 10° C. or higher than 10° C.

7. The method according to claim 6, wherein
the adhesive member is solder selected any one of Sb—Ag—Cu—Sn, Pb—In—Ag, and Pb—Sn.

8. The method according to claim 1, wherein
the first connector is made of any one of Cu (copper), a Cu (copper) alloy, Mo (molybdenum), and AlSiC.

9. The method according to claim 1, wherein
the pressurizing process are performed by using a first plate just below the first electrode terminal and a second plate disposed on the first connector.

10. The method according to claim 1, wherein
in the pressurizing process, the first connector, the adhesive member, the semiconductor element, the first electrode terminal, and the second electrode terminal are pressurized, after the temperature raises up at the first solid phase temperature.

11. A semiconductor device comprising:
a semiconductor element provided on a first electrode terminal via a first portion of an adhesive member; and
a first connector having one end provided on a first electrode of the semiconductor element via a second portion of the adhesive member and the other end provided on a second electrode terminal via a third portion of the adhesive member, the one end being bonded to the first electrode and the other end being bonded to the second electrode terminal, wherein
the adhesive member is solder selected any one of Sn—Ge, Sn—Zn, Sb—Ag—Cu—Sn, Pb—In—Ag, and Pb—Sn having characteristics that a liquid phase is equal to 260° C. or higher than 260° C. and a temperature difference between solid phase and liquid phase is equal to 10° C. or higher than 10° C.

12. The device according to claim 11, further comprising
a second connector having one end provided on a second electrode of the semiconductor element via a fourth portion of the adhesive member and the other end provided on a third electrode terminal via a fifth portion of the adhesive member, the one end being bonded to the second electrode and the other end being bonded to the third electrode terminal.

13. A semiconductor device comprising:
a semiconductor element provided on a first electrode terminal via a first portion of an adhesive member; and
a first connector having one end provided on a first electrode of the semiconductor element via a second portion of the adhesive member and the other end provided on a second electrode terminal via a third portion of the adhesive member, the one end being bonded to the first electrode and the other end being bonded to the second electrode terminal, wherein
the adhesive member is solder selected any one of Sb—Ag—Cu—Sn, Pb—In—Ag, and Pb—Sn having characteristics that a liquid phase is equal to 260° C. or higher than 260° C. and a temperature difference between solid phase and liquid phase is equal to 10° C. or higher than 10° C.

14. The device according to claim 13, further comprising
a second connector having one end provided on a second electrode of the semiconductor element via a fourth portion of the adhesive member and the other end provided on a third electrode terminal via a fifth portion of the adhesive member, the one end being bonded to the second electrode and the other end being bonded to the third electrode terminal.

15. The device according to claim 14, wherein
a bonding wire bonds a third electrode of the semiconductor element to a fourth electrode terminal.
